(19) United States
(12) Patent Application Publication
(10) Pub. No.: US 2016/0248035 A1
(43) Pub. Date: Aug. 25, 2016

(54) LIGHT EMITTING DISPLAY DEVICE AND METHOD OF MANUFACTURING THE SAME

(71) Applicant: SAMSUNG DISPLAY CO., LTD., Yongin-si (KR)

(72) Inventors: Jae Kwon Hwang, Seoul (KR); Yool Guk Kim, Anyang-si (KR)

(21) Appl. No.: 14/835,087

(22) Filed: Aug. 25, 2015

(30) Foreign Application Priority Data
Feb. 25, 2015 (KR) 10-2015-0026583

(51) Int. Cl. H01L 51/50; H01L 27/32; H01L 51/56

(52) U.S. Cl. CPC H01L 51/5096; H01L 51/56; H01L 27/3246; H01L 2227/323

(57) ABSTRACT

A light emitting display device includes a substrate including a plurality of pixels, a first electrode, a pixel defining layer on the substrate and having an opening exposing the first electrode, a light emitting layer extending along a side surface of the pixel defining layer from the first electrode in the opening of the pixel defining layer, and including a first portion located on the first electrode and a second portion located on the side surface of the pixel defining layer, the second portion having a thickness decreasing in a direction toward an upper surface of the pixel defining layer from the side surface of the pixel defining layer, a second electrode, and a leakage current blocking layer having a uniform thickness on the side surface of the pixel defining layer between the first electrode and the light emitting layer or between the light emitting layer and the second electrode.

### CROSS-REFERENCE TO RELATED APPLICATIONS

This application claims priority to and the benefit of Korean Patent Application No. 10-2015-0026583, filed on Feb. 25, 2015 in the Korean Intellectual Property Office, the disclosure of which is incorporated herein in its entirety by reference.

### BACKGROUND

1. Field

The present invention relates to a light emitting display device and method of manufacturing the same.

2. Description of the Prior Art

Among light emitting display devices, an organic light emitting display device is a self-luminous display device that has the features of wide viewing angle, superior contrast, and high response speed, and thus has been recognized as the next-generation display device.

An organic light emitting display device has an organic light emitting layer that is made of an organic light emitting material disposed between an anode electrode and a cathode electrode. When anode and cathode voltages are respectively applied to these electrodes, holes injected from the anode electrode move to the organic light emitting layer through a hole injection layer and a hole transport layer, and electrons move to the organic light emitting layer through an electron injection layer and an electron transport layer. In the organic light emitting layer, the electrons and the holes are recombined, and through this recombination, excitons are generated. As the generated excitons return from an excited state to a ground state, the organic light emitting layer emits light to display an image.

### SUMMARY

The organic light emitting display device includes a pixel defining layer having an opening for exposing an anode electrode that is formed for each of pixels, and a hole injection layer, a hole transport layer, an organic light emitting layer, an electron transport layer, an electron injection layer, and a cathode electrode, which are formed on the anode electrode that is exposed through the opening of the pixel defining layer. In particular, the organic light emitting layer may be formed by discharging a light emitting solution including a light emitting material into the opening of the pixel defining layer using an inkjet printing method, a nozzle printing method, or the like.

On the other hand, to prevent or substantially prevent the light emitting solution from going out of the opening of the pixel defining layer when forming the light emitting layer by discharging the light emitting solution into the opening of the pixel defining layer (using, e.g., an inkjet printing method or a nozzle printing method), the pixel defining layer is formed to have a lyophobic property.

However, even when the pixel defining layer has the lyophobic property, the light emitting solution has a small wetting property to the pixel defining layer. Accordingly, the light emitting layer formed by discharging the light emitting solution into the opening of the pixel defining layer may have a thickness that decreases toward a side surface of the pixel defining layer from the anode electrode. In this case, a leakage current may occur between the anode electrode and the cathode electrode in the portion in which the thickness of light emitting layer is decreased. As a result, light emission efficiency of the light emitting layer may be reduced and display quality of the light emitting display device may deteriorate.

Accordingly, one aspect of the present invention is to provide a light emitting display device, which may decrease the deterioration of light emission efficiency of the light emitting layer by decreasing the leakage current occurring between the anode electrode and the cathode electrode, and thereby decrease the deterioration of display quality.

Another aspect of the present invention is to provide a method of manufacturing a light emitting display device, which may decrease the deterioration of light emission efficiency of the light emitting layer by decreasing the leakage current occurring between the anode electrode and the cathode electrode, and thereby decrease the deterioration of display quality.

Additional aspects and features of the invention will be set forth in part in the description which follows and in part will become apparent to those having ordinary skill in the art upon examination of the following or may be learned from practice of the invention.

In accordance with one embodiment of the present invention, there is provided a light emitting display device including: a substrate including a plurality of pixels arranged in a first direction and a second direction crossing the first direction; a first electrode for each of the plurality of pixels on the substrate; a pixel defining layer on the substrate and having an opening exposing the first electrode; a light emitting layer extending along a side surface of the pixel defining layer from the first electrode in the opening of the pixel defining layer, and including a first portion located on the first electrode and a second portion located on the side surface of the pixel defining layer, the second portion having a thickness decreasing in a direction toward an upper surface of the pixel defining layer from the side surface of the pixel defining layer; a second electrode on the light emitting layer; and a leakage current blocking layer having a uniform thickness on the side surface of the pixel defining layer between the first electrode and the light emitting layer or between the light emitting layer and the second electrode.

In an embodiment, the leakage current blocking layer has an electric resistance higher than an electric resistance of the light emitting layer.

In an embodiment, the leakage current blocking layer includes an organic insulating material or an inorganic insulating material.

In an embodiment, the leakage current blocking layer has a continuous form between adjacent ones of the pixels.

In an embodiment, the leakage current blocking layer has first blocking portions and second blocking portions that cross, the first blocking portions extending along the second direction and between openings of the pixel defining layer separated along the first direction, and the second blocking portions extending along the first direction and between openings of the pixel defining layer separated along the second direction.

In an embodiment, the light emitting display device further includes a hole injection layer between the first electrode and the light emitting layer in the opening of the pixel defining layer, the hole injection layer having a thickness decreasing toward the side surface of the pixel defining layer from the first electrode, wherein the leakage current blocking layer is between the hole injection layer and the light emitting layer.

In an embodiment, the light emitting display device further includes a hole injection layer between the first electrode and the light emitting layer in the opening of the pixel defining layer, the hole injection layer having a thickness decreasing toward the side surface of the pixel defining layer from the first electrode, and a hole transport layer between the hole injection layer and the light emitting layer in the opening of the pixel defining layer, the hole transport layer having a thickness decreasing toward the side surface of the pixel defining layer from the first electrode, wherein the leakage current blocking layer is between the hole transport layer and the light emitting layer.

In an embodiment, the light emitting display device further includes an electron transport layer between the light emitting layer and the second electrode, wherein the leakage current blocking layer is between the light emitting layer and the electron transport layer.

In accordance with one embodiment of the present invention, there is provided a light emitting display device including: a substrate including a plurality of pixels arranged in a first direction and a second direction crossing the first direction; a first electrode for each of the plurality of pixels on the substrate; a pixel defining layer on the substrate and has an opening exposing the first electrode; a light emitting layer extending along a side surface of the pixel defining layer from the first electrode in the opening of the pixel defining layer; a second electrode on the light emitting layer; and a leakage current blocking layer extending from the side surface of the pixel defining layer to an upper surface of the pixel defining layer between the first electrode and the light emitting layer or between the light emitting layer and the second electrode and having a continuous form between adjacent pixels.

In an embodiment, the leakage current blocking layer has an electric resistance higher than an electric resistance of the light emitting layer.

In an embodiment, the leakage current blocking layer is formed of an organic insulating material or an inorganic insulating material.

In an embodiment, the leakage current blocking layer has first blocking portions and second blocking portions that cross, the first blocking portions extending along the second direction and between openings of the pixel defining layer separated along the first direction, and the second blocking portions extending along the first direction and between openings of the pixel defining layer separated along the second direction.

In an embodiment, the light emitting layer includes a first portion on the first electrode and a second portion on the side surface of the pixel defining layer, the second portion having a thickness decreasing in a direction toward an upper surface of the pixel defining layer from the side surface of the pixel defining layer.

In an embodiment, the light emitting display device further includes a hole injection layer between the first electrode and the light emitting layer in the opening of the pixel defining layer, the hole injection layer having a thickness decreasing toward the side surface of the pixel defining layer from the first electrode, wherein the leakage current blocking layer is between the hole injection layer and the light emitting layer.

In an embodiment, the light emitting display device further includes a hole injection layer between the first electrode and the light emitting layer in the opening of the pixel defining layer, the hole injection layer having a thickness decreasing toward the side surface of the pixel defining layer from the first electrode, and a hole transport layer between the hole injection layer and the light emitting layer in the opening of the pixel defining layer, the hole transport layer having a thickness decreasing toward the side surface of the pixel defining layer from the first electrode, wherein the leakage current blocking layer is between the hole transport layer and the light emitting layer.

In an embodiment, the light emitting display device further includes an electron transport layer between the light emitting layer and the second electrode, wherein the leakage current blocking layer is between the light emitting layer and the electron transport layer.

In accordance with one embodiment of the present invention, there is provided a method of manufacturing a light emitting display device, the method including: forming a first electrode, on a substrate including a plurality of pixels arranged in a first direction and a second direction that crosses the first direction, for each of the plurality of pixels; forming a pixel defining layer on the substrate and has an opening exposing the first electrode; forming a light emitting layer along a side surface of the pixel defining layer from the first electrode in the opening of the pixel defining layer, the light emitting layer including a first portion located on the first electrode and a second portion located on the side surface of the pixel defining layer, the second portion having a thickness decreasing in a direction toward an upper surface of the pixel defining layer from the side surface of the pixel defining layer; forming a second electrode on the light emitting layer; and forming a leakage current blocking layer, having a uniform thickness, on the side surface of the pixel defining layer between the first electrode and the light emitting layer or between the light emitting layer and the second electrode.

In an embodiment, the forming the leakage current blocking layer includes: disposing a first mask having first openings on the substrate, the first openings exposing side portions of the pixel defining layer facing each other in the first direction in the opening of the pixel defining layer; forming first blocking portions by depositing a material forming the leakage current blocking layer on a side surface and an upper surface of the pixel defining layer that are exposed through the first openings of the first mask using a deposition method; disposing a second mask having second openings on the substrate, the second openings exposing side portions of the pixel defining layer facing each other in the second direction in the opening of the pixel defining layer; and forming second blocking portions by depositing the material forming the leakage current blocking layer on a side surface and an upper surface of the pixel defining layer that are exposed through the second openings of the second mask using the deposition method.

In an embodiment, the first openings extend along the second direction and have a continuous form between adjacent openings of the pixel defining layer in the first direction, and the second openings extend along the first direction and have a continuous form between adjacent openings of the pixel defining layer in the second direction.

In an embodiment, the method further includes: forming a hole injection layer, between the first electrode and the light emitting layer in the opening of the pixel defining layer, having a thickness decreasing toward the side surface of the pixel defining layer from the first electrode; forming a hole transport layer, between the hole injection layer and the light emitting layer in the opening of the pixel defining layer, having a thickness decreasing toward the side surface of the pixel defining layer from the first electrode; and forming an electron transport layer between the light emitting layer and the second electrode in the opening of the pixel defining layer, wherein the forming the leakage current blocking layer includes disposing the leakage current blocking layer between the hole injection layer and the hole transport layer, between the hole transport layer and the light emitting layer, or between the light emitting layer and the electron transport layer.

According to embodiments of the present invention, at least the following effects may be achieved.

The light emitting display device according to an embodiment of the present invention includes the leakage current blocking layer, with a uniform thickness, disposed on the side surface of the pixel defining layer between the first electrode and the light emitting layer at a region where a distance between the first electrode and the second electrode becomes smaller due to the portion having a decreasing thickness in the light emitting layer. This is because the light emitting layer disposed in the opening of the pixel defining layer has decreasing thickness at the portion corresponding to the side surface of the pixel defining layer.

Accordingly, the light emitting display device according to an embodiment of the present invention may decrease the deterioration of light emission efficiency of the light emitting layer by decreasing or preventing the occurrence of a leakage current between the first electrode and the second electrode to thereby decrease the deterioration of display quality.

The effects according to the present invention are not limited to the contents as exemplified above, but further various effects are included in the description.

### BRIEF DESCRIPTION OF THE DRAWINGS

The above and other features and aspects of the present invention will be more apparent from the following detailed description taken in conjunction with the accompanying drawings, in which:

FIG. 1 is a schematic plan view of a plurality of pixels of a light emitting display device according to an embodiment of the present invention;

FIG. 2 is a cross-sectional view taken along the line I-I′ of FIG. 2;

FIG. 3 is an enlarged cross-sectional view of portion A of FIG. 2;

FIG. 4 is a plan view of a leakage current blocking layer of FIG. 2;

FIG. 5 is cross-sectional view of a light emitting display device according to another embodiment of the present invention;

FIG. 6 is cross-sectional view of a light emitting display device according to still another embodiment of the present invention;

FIG. 7 is cross-sectional view of a light emitting display device according to still another embodiment of the present invention;

FIG. 8 is cross-sectional view of a light emitting display device according to still another embodiment of the present invention;

FIG. 9 is cross-sectional view of a light emitting display device according to still another embodiment of the present invention; and

FIGS. 10 through 20 are views illustrating a method of manufacturing a light emitting display device according to an embodiment of the present invention.

### DETAILED DESCRIPTION

Aspects and features of the present invention and methods of accomplishing the same may be understood more readily by reference to the following detailed description of exemplary embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will be defined by the appended claims, and equivalents thereof.

Hereinafter, embodiments of the present invention will be described with reference to the accompanying drawings.

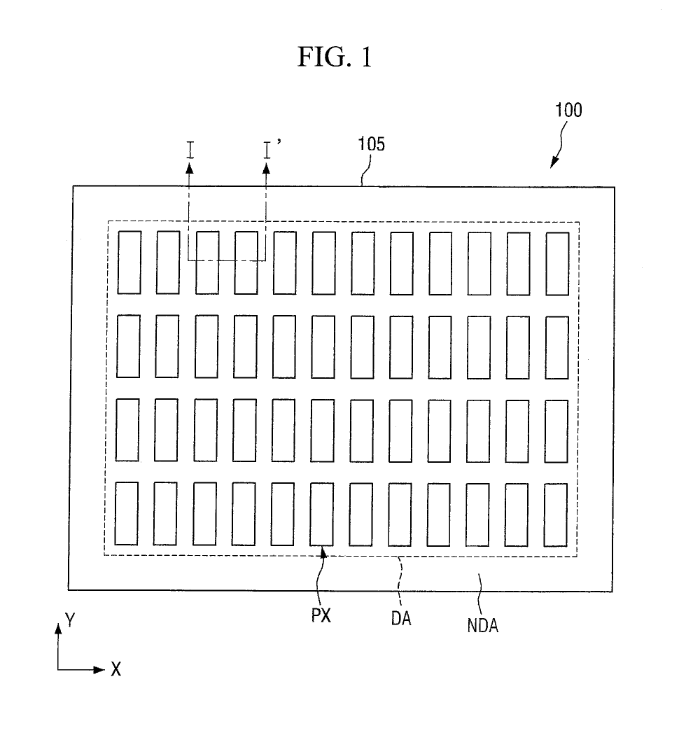

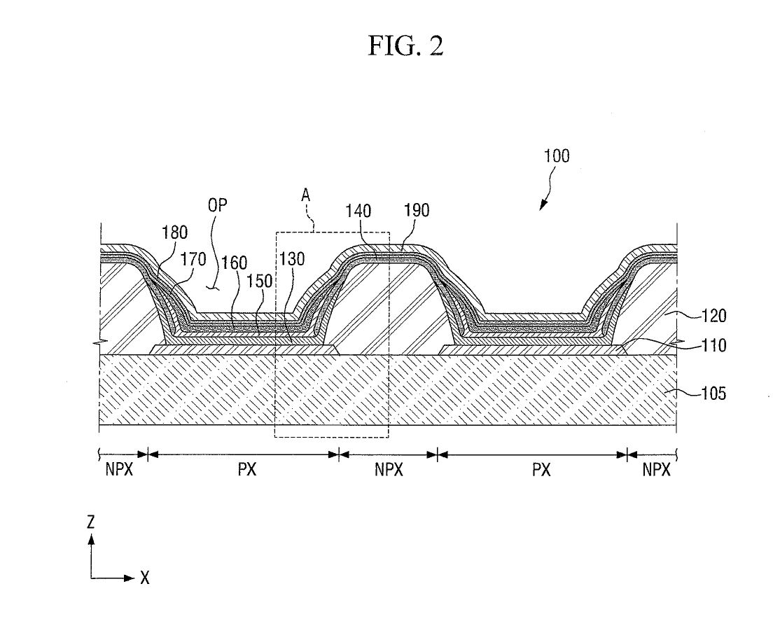

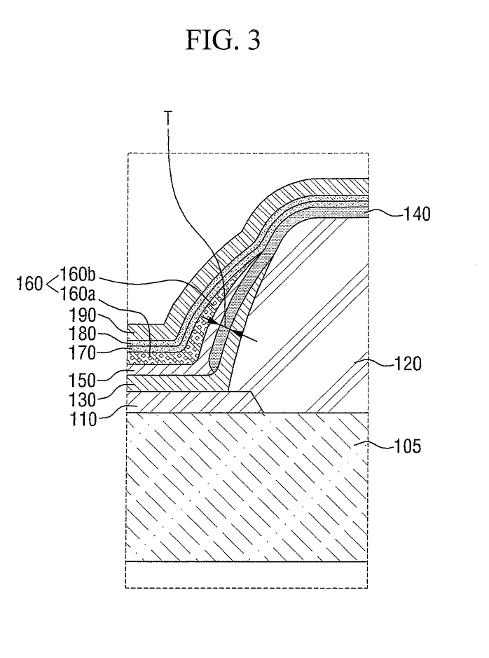

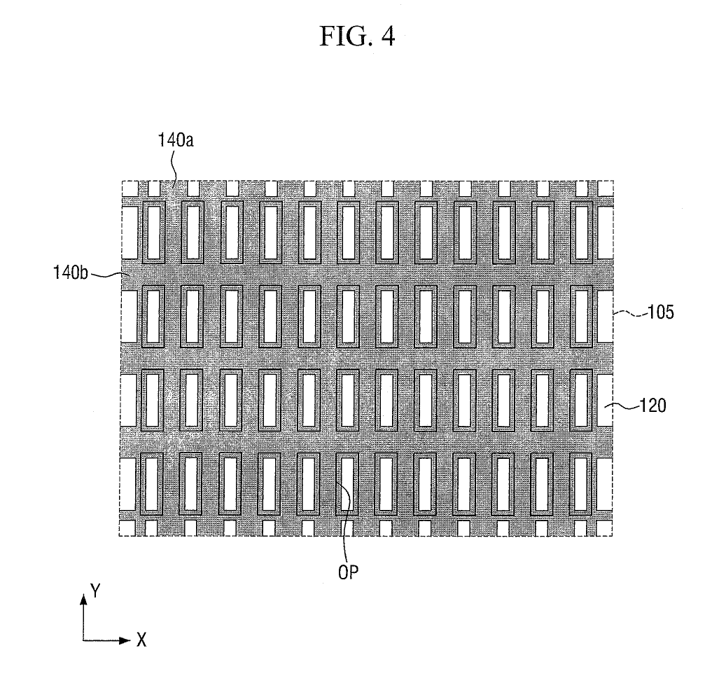

FIG. 1 is a schematic plan view of a plurality of pixels of a light emitting display device according to an embodiment of the present invention. FIG. 2 is a cross-sectional view taken along the line I-I′ of FIG. 2. FIG. 3 is an enlarged cross-sectional view of portion A of FIG. 2. FIG. 4 is a plan view of a leakage current blocking layer of FIG. 2.

Referring to FIGS. 1 and 2, a light emitting display includes a substrate 105, a first electrode 110, a pixel defining layer 120, a hole injection layer 130, a leakage current blocking layer 140, a hole transport layer 150, a light emitting layer 160, an electron transport layer 170, an electron injection layer 180, and a second electrode 190. These layers (or members) are sequentially stacked along a Z direction of FIG. 2.

The substrate 105 includes a display area DA including a plurality of pixels PX displaying an image and a non-display area NDA located outside the display area DA. The pixels PX are disposed along a first direction X and a second direction Y, which crosses the first direction X, to have a matrix form, and include red pixels that emit red light, green pixels that emit green light, and blue pixels that emit blue light. As shown in FIG. 2, a non-pixels region NPX is defined between adjacent pixels PX in the display area DA of the substrate 105.

The substrate 105 may include an insulating substrate. The insulating substrate may be formed of a transparent glass material having SiO₂ as a main component. In some embodiments, the insulating substrate may be made of an opaque material, a plastic material, and/or the like. Further, the insulating substrate may be a flexible substrate.

The substrate 105 may further include other structures formed on the insulating substrate. Examples of the structures include wirings, electrodes, and insulating layers. In some embodiments, the substrate 105 may include a plurality of thin-film transistors (TFTs) formed on the insulating substrate. Drain electrode of a TFT may be electrically connected to the first electrode 110. Each of the TFTs may include an active region made of amorphous silicon, polycrystalline silicon, monocrystalline silicon, and/or the like. In another embodiment, each of the TFTs may include an active region made of an oxide semiconductor.

The first electrode 110 is formed for each pixel PX on the substrate 105. The first electrode 110 may be an anode electrode, which provides holes to the light emitting layer 160 in response to a signal transmitted to a corresponding TFT, or a cathode electrode, which provides electrons to the light emitting layer 160 in response to the signal transmitted to the TFT. The first electrode 110 may be used as a transparent electrode or a reflective electrode. To be used as a transparent electrode, the first electrode 110 may be formed of indium tin oxide (ITO), indium zinc oxide (IZO), zinc oxide (ZnO), In₂O₃, and/or the like. To be used as a reflective electrode, the first electrode 110 may be formed by forming a reflective film using Ag, Mg, Al, Pt, Pd, Au, Ni, Nd, Ir, Cr, and/or the like, or a compound of the same, and then forming ITO, IZO, ZnO, In₂O₃, and/or the like on the reflective film. The first electrode 110 may be formed by, for example, a photolithography method, or may be formed by any other suitable method.

The pixel defining layer 120 is disposed on the substrate 105 so as to have an opening OP exposing the first electrode 110 to partition respective pixels PX. The pixel defining layer 120 enables the hole injection layer 130 to be formed on the first electrode 110 through the opening OP. The pixel defining layer 120 may be made of an insulating material.

In an embodiment of the present invention, the pixel defining layer 120 is formed to have a lyophobic property in order to prevent or substantially prevent a hole injection solution from leaving (e.g., going out of) the opening OP of the pixel defining layer 120 when forming the hole injection layer 130 by discharging the hole injection solution into the opening OP of the pixel defining layer 120 using an ink printing method, a nozzle printing method, or the like. The pixel defining layer 120 may be formed of an insulating material that makes the contact angle of the hole injection solution against the pixel defining layer 120 become greater than or equal to about 40°. For example, the pixel defining layer 120 may be formed of an organic insulating material including fluorine, and/or the like. The organic insulating material may be at least one polymer resin selected from the group including benzo cyclo butane (BCB), polyimide (PI), poly amaide (PA), acryl resin, phenol resin, and/or the like. The pixel defining layer 120 may be formed by a photolithography method, but is not limited thereto. The inkjet printing method refers to dropping a material to be printed at a desired location in the form of ink droplets, and the nozzle printing method refers to making a material to be flowed in the form of a solution along a line including a desired location.

The hole injection layer 130 is disposed along the first electrode 110 and the side surface of the pixel defining layer 120 in the opening OP of the pixel defining layer 120. The hole injection layer 130 is formed by discharging a hole injection solution including a hole injection material into the opening OP of the pixel defining layer 120 using an inkjet printing method, a nozzle printing method, or the like. In this case, the hole injection layer 130 may have a thickness decreasing toward the side surface of the pixel defining layer 120 from the first electrode 110. This is because the hole injection solution has a small wetting property to the pixel defining layer 120 although the pixel defining layer 120 has a lyophobic property. For example, the hole injection layer 130 may include a first portion located on the first electrode 110 and a second portion located on the side surface of the pixel defining layer 120. The first portion may have a uniform thickness, and the second portion may have a thickness decreasing in a direction toward the upper surface of the pixel defining layer 120 from the side surface of the pixel defining layer 120.

The hole injection layer 130 is a buffer layer that lowers an energy barrier between the first electrode 110 and the hole transport layer 150. The hole injection layer 130 facilitates the injection of holes from the first electrode 110 to the hole transport layer 150. The hole injection layer 130 is formed to be an organic compound such as 4,4′,4″-tris(3-methylphenylphenylamino)triphenylamine (MTDATA), copper phthalocyanine (CuPc), or poly(3,4-ethylenedioxythiphene, polystyrene sulfonate) (PEDOT/PSS), and/or the like.

The leakage current blocking layer 140 is disposed on the side surface of the pixel defining layer 120 between the first electrode 110 and the light emitting layer 160. For example, the leakage current blocking layer 140 may be disposed on the side portion of the hole injection layer 130, at a region in which the side portion of the hole injection layer 130 is disposed on the side surface of the pixel defining layer 120. Accordingly, the leakage current blocking layer 140 may be disposed at a region where a distance between the first electrode 110 and the second electrode 190 becomes smaller, which corresponds to the portion of the light emitting layer 160 having decreasing thickness (i.e., the second portion 160b of FIG. 3). This is because the light emitting layer 160 disposed in the opening OP of the pixel defining layer 120 has decreasing thickness at the portion corresponding to the side surface of the pixel defining layer 120. Thus, the leakage current blocking layer 140 may decrease or prevent the occurrence of a leakage current between first electrode 110 and the second electrode 190, which may otherwise result from the thinned portion (the second portion 160b of FIG. 3) of the light emitting layer 160. In the example shown in FIG. 3, the element having a thickness decreasing at the portion corresponding to the side surface of the pixel defining layer 120 is the light emitting layer 160, however, the element may include at least one of the hole injection layer 130 and the hole transport layer 150.

In some embodiments, the leakage current blocking layer 140 may not be formed on a portion of the light emitting layer 160 having increased thickness (i.e., the first portion 160a of FIG. 3).

The leakage current blocking layer 140 is formed to have a lyophobic property in order to prevent or substantially prevent a hole transport solution from going out of (or reaching beyond) the opening OP of the pixel defining layer 120 when forming the hole transport layer 150. The leakage current blocking layer 140 may be formed by discharging the hole transport solution into the opening OP of the pixel defining layer 120 using an ink printing method, a nozzle printing method, or the like, while having an electric resistance higher than an electric resistance of the light emitting layer 160 to prevent or substantially prevent a leakage current from flowing between the first electrode 110 and the second electrode 190. Thus, the leakage current blocking layer 140 may be formed of an insulating material that makes the contact angle of the hole transport solution against the leakage current blocking layer 140 become greater than or equal to about 40°. For example, the leakage current blocking layer 140 may be formed of an organic insulating material including fluorine, and/or the like. The organic insulating material may be at least one polymer resin selected from the group including benzo cyclo butane (BCB), polyimide (PI), poly amaide (PA), acryl resin, phenol resin, and the like.

The leakage current blocking layer 140 may have a uniform thickness T. Accordingly, the leakage current blocking layer 140 may decrease or prevent the occurrence of a leakage current between first electrode 110 and the second electrode 190 by reducing the region where the interval between the first electrode 110 and the second electrode 190 is decreased, which may occur in a case that the light emitting layer 160 disposed in the opening OP of the pixel defining layer 120 has a thickness decreasing toward the side surface of the pixel defining layer 120 from the first electrode 110, and may also occur in a case that the light emitting layer 160 has a thin thickness on the side surface of the pixel defining layer 120 due to its other pattern such as uneven shape. The leakage current blocking layer 140 may be formed using a deposition method to have the uniform thickness T. The deposition method may be a method through which it is easy to control forming the leakage current blocking layer 140 at a desire position. As the deposition method, an evaporation deposition method evaporating a deposition material to deposit at a desire position may be selected.

The leakage current blocking layer 140 may be formed to extend from the side surface of the pixel defining layer 120 to the upper surface of the pixel defining layer 120 so as to have a continuous form between the adjacent pixels PX in a plan view. In this case, as illustrated in FIG. 4, the leakage current blocking layer 140 may be formed such that first blocking portions 140a and second blocking portions 140b cross, in which the first blocking portions 140a extend along the second direction Y on the upper surface of the pixel defining layer 120 and are disposed between openings OP of the pixel defining layer 120 separated along the first direction X, and the second blocking portions 140b extended along the first direction X on the upper surface of the pixel defining layer 120 and are disposed between openings OP of the pixel defining layer 120 separated along the second direction Y.

The hole transport layer 150 may be disposed on the hole injection layer 130 and the leakage current blocking layer 140 in the opening OP of the pixel defining layer 120. The hole transport layer 150 may be formed by discharging a hole transport solution including a hole transport material into the opening OP of the pixel defining layer 120 using an inkjet printing method, a nozzle printing method, or the like. In this case, the hole transport layer 150 may have a thickness decreasing toward the side surface of the pixel defining layer 120 from the first electrode 110. This is because the hole transport solution has a small wetting property to the leakage current blocking layer 140 although the leakage current blocking layer 140 has a lyophobic property. For example, the hole transport layer 150 may include a first portion located on the first electrode 110 and a second portion located on the side surface of the pixel defining layer 120. The first portion may have a uniform thickness, and the second portion may have a thickness decreasing in a direction toward the upper surface of the pixel defining layer from the side surface of the pixel defining layer 120.

The hole transport layer 150 transports holes provided from the hole injection layer 130 to the light emitting layer 160. The hole transport layer 150 is formed of the hole transport material having an electrical conductivity lower than that of the hole injection layer 130. The hole transport layer 150 may be formed of an organic compound such as N,N′-diphenyl-N,N′-bis(3-methylphenyl)-1,1′-bi-phenyl-4,4′-diamine (TPD) or N,N′-di(naphthalen-1-yl)-N,N′-diphenyl-benzidine (NPB), and/or the like.

The light emitting layer 160 may be disposed on the hole transport layer 150 in the opening OP of the pixel defining layer 120. The light emitting layer 160 may be formed by discharging a light emitting solution including a light emitting material into the opening OP of the pixel defining layer 120 using an inkjet printing method, a nozzle printing method, or the like. In this case, the light emitting layer 160 may have a thickness decreasing toward the side surface of the pixel defining layer 120 from the first electrode 110. This is because the light emitting solution has a small wetting property to the leakage current blocking layer 140 although the leakage current blocking layer 140 has a lyophobic property. For example, the light emitting layer 160 may include a first portion 160a located on the first electrode 110 and a second portion 160b located on the side surface of the pixel defining layer 120. The first portion 160a may have a uniform thickness, and the second portion 160b may have a thickness decreasing in a direction toward the upper surface of the pixel defining layer from the side surface of the pixel defining layer 120.

The light emitting layer 160 emits light when holes received from the first electrode 110 and electrons received from the second electrode 190 recombine. More For example, holes and electrons provided to the light emitting layer 160 may combine to form excitons. When the excitons change from an excited state to a ground state, the light emitting layer 160 may emit light. The light emitting layer 160 may be formed of a light emitting material having an electrical conductivity that is lower than an electrical conductivity of the hole injection layer 130 and is similar to the electrical conductivity of the hole transport layer 150. The light emitting layer 160 may include a red light emitting layer that emits red light, a green light emitting layer that emits green light, and a blue light emitting layer that emits blue light.

The red light emitting layer may include one red light emitting material or a host and a red dopant. Examples of the host of the red light emitting layer may include, but are not limited to, Alq₃, 4,4′-N,N′-dicarbazol-biphenyl (CBP), ploy(n-vinylcarbazole) (PVK), 9,10-Di(naphthyl-2-yl)anthracene (ADN), 4,4′,4″-tris(N-carbazolyl)triphenylamine (TCTA), 1,3,5-tris(N-phenylbenzimidazol-2-yl)benzene (TPBI), 3-tert-butyl-9,10-di(naphth-2-yl) anthracene (TBADN), terfluorene (E3), distyrylarylene (DSA). In addition, examples of the red dopant may include, but are not limited to, PtOEP, Ir(piq)₃, and Btp₂Ir(acac).

The green light emitting layer may include one green light emitting material or a host and a green dopant. The host of the red light emitting layer may be used as the host of the green light emitting layer. Examples of the green dopant may include, but are not limited to, Ir(ppy)₃, Ir(ppy)₂(acac), and Ir(mpyp)₃.

The blue light emitting layer may include one blue light emitting material or a host and a blue dopant. The host of the red light emitting layer may be used as the host of the blue light emitting layer. Examples of the blue dopant may include, but are not limited to, F₂Irpic, (F₂ppy)₂Ir(tmd), Ir(dfppz)₃, ter-fluorene, 4,4′-bis(4-diphenylaminostyryl) biphenyl (DPAVBi), 2,5,8,11-tetra-ti-butyl pherylene (TBPe).

The electron transport layer 170 may be disposed on the light emitting layer 160 to have a continuous form between the adjacent pixels PX. The electron transport layer 170 transports electrons provided from the second electrode 190 via the electron injection layer 180 to the light emitting layer 160. The electron transport layer 170 may be formed of an organic compound such as 4,7-diphenyl-1,10-phenanthroline) (Bphen), BAlq, tris(8-quinolinorate)aluminum (Alq3), berylliumbis(benzoquinolin-10-olate) (Bebq₂), TPBI, and/or the like. The electron transport layer 170 may be formed by, for example, a deposition method, or any other suitable method.

The electron injection layer 180 may be disposed on the electron transport layer 170. The electron injection layer 180 is a buffer layer that lowers an energy barrier between the electron transport layer 170 and the second electrode 190. The electron injection layer 180 facilitates the injection of electrons from the second electrode 190 to the electron transport layer 170. The electron injection layer 180 may be formed of LiF, CsF, and/or the like. The electron injection layer 180 may be formed by, for example, a deposition method, or any other suitable method.

The second electrode 190 may be formed on the electron injection layer 180 and may be a cathode electrode providing electrons to the light emitting layer 160 or an anode electrode providing holes to the light emitting layer 160. Like the first electrode 110, the second electrode 190 may be used as a transparent electrode or a reflective electrode. The second electrode 190 may be formed by, for example, a deposition method, or any other suitable method.

The light emitting display device 100 may further include an encapsulation substrate placed on the second electrode 190. The encapsulation substrate may be made of an insulating substrate. A spacer may be disposed between the second electrode 190 on the pixel defining layer 120 and the encapsulation substrate. In some other embodiments of the present invention, the encapsulation substrate may be omitted. In this case, an encapsulation layer made of an insulating material may cover, and thus protect, the entire structure.

As described above, the light emitting display device 100 according to an embodiment of the present invention includes the leakage current blocking layer 140, with a uniform thickness, disposed on the side surface of the pixel defining layer 120 between the first electrode 110 and the light emitting layer 160 at a region where a distance between the first electrode 110 and the second electrode 190 becomes smaller due to the portion having decreasing thickness in the light emitting layer 160. This is because the light emitting layer 160 disposed in the opening OP of the pixel defining layer 120 has a decreasing thickness at the portion corresponding to the side surface of the pixel defining layer 120.

Accordingly, the light emitting display device 100 according to an embodiment of the present invention may decrease the deterioration of light emission efficiency of the light emitting layer 160 by decreasing or preventing the occurrence of a leakage current between the first electrode 110 and the second electrode 190, and thus the deterioration of display quality may be decreased.

Next, a light emitting display device 200 according to another embodiment of the present invention will be described.

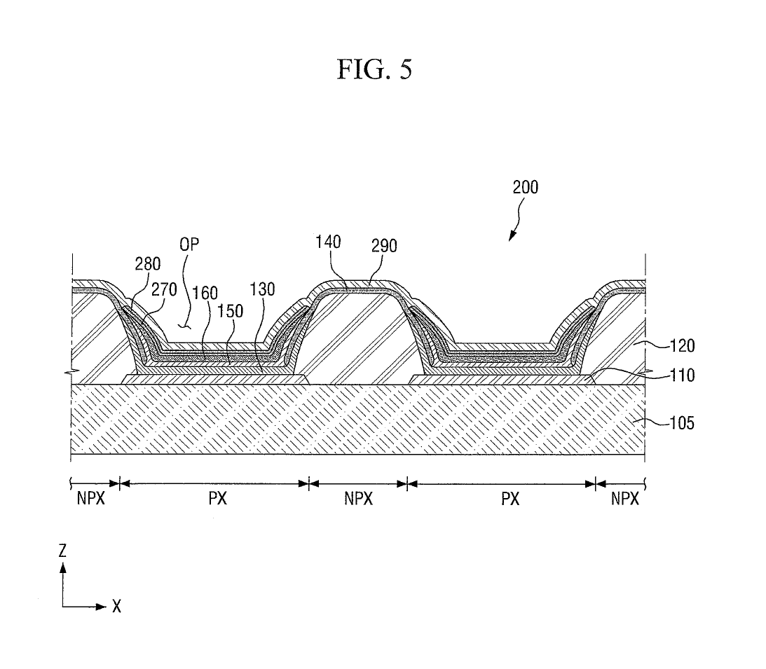

FIG. 5 is cross-sectional view of a light emitting display device according to another embodiment of the present invention.

Referring to FIG. 5, the light emitting display device 200 according to another embodiment of the present invention has the same or substantially the same configuration as the configuration of the light emitting display device 100 of FIG. 1 except for an electron transport layer 270, an electron injection layer 280, and a second electrode 290. Accordingly, explanation of the light emitting display device 200 according to another embodiment of the present invention will be primarily focused on the electron transport layer 270, the electron injection layer 280, and the second electrode 290.

The light emitting display device 200 according to another embodiment of the present invention includes substrate 105, a first electrode 110, a pixel defining layer 120, a hole injection layer 130, a leakage current blocking layer 140, a hole transport layer 150, a light emitting layer 160, an electron transport layer 270, an electron injection layer 280, and a second electrode 290. These members are sequentially stacked in a Z direction of FIG. 5.

The electron transport layer 270 is similar to the electron transport layer 170 of FIG. 2. However, the electron transport layer 270 is only disposed on the light emitting layer 160. That is, the electron transport layer 170 is formed to have a divided form between the adjacent pixels PX.

The electron injection layer 280 is similar to the electron injection layer 180 of FIG. 2. However, the electron injection layer 280 is formed to correspond to the electron transport layer 270, which is formed to have a divided form between the adjacent pixels PX.

The second electrode 290 is similar to the second electrode 190 of FIG. 2. However, the second electrode 290 contacts a partial portion of the leakage current blocking layer 140 exposed by the electron injection layer 280, which is formed to have a divided form between the adjacent pixels PX.

As described above, the light emitting display device 200 according to another embodiment of the present invention includes the leakage current blocking layer 140, with a uniform thickness, disposed on the side surface of the pixel defining layer 120 between the first electrode 110 and the light emitting layer 160 at a region where a distance between the first electrode 110 and the second electrode 190 becomes smaller due to the portion having a decreasing thickness in the light emitting layer 160. This is because the light emitting layer 160 disposed in the opening OP of the pixel defining layer 120 has decreasing thickness at the portion corresponding to the side surface of the pixel defining layer 120.

Accordingly, the light emitting display device 200 according to another embodiment of the present invention may decrease the deterioration of light emission efficiency of the light emitting layer 160 by decreasing or preventing the occurrence of a leakage current between the first electrode 110 and the second electrode 290, and thus the deterioration of display quality may be decreased.

Next, a light emitting display device 300 according to still another embodiment of the present invention will be described.

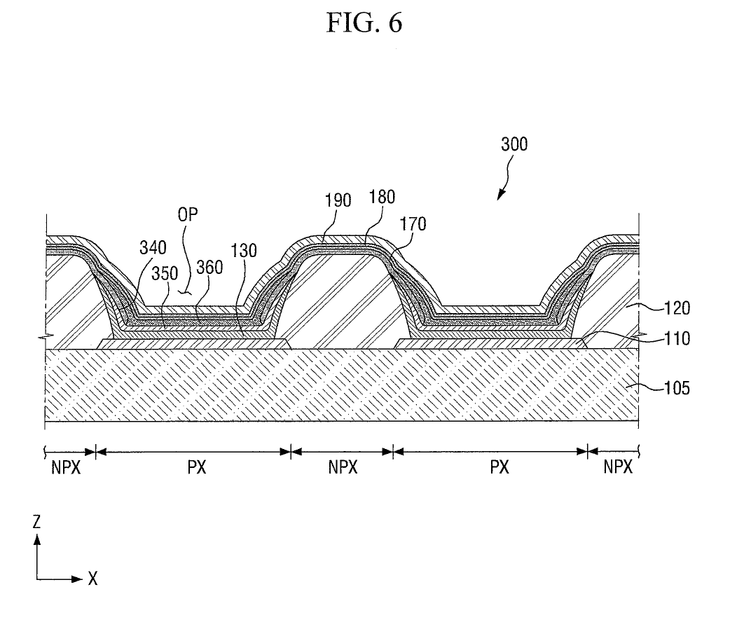

FIG. 6 is cross-sectional view of a light emitting display device according to still another embodiment of the present invention.

Referring to FIG. 6, the light emitting display device 300 according to still another embodiment of the present invention has the same or substantially the same configuration as the configuration of the light emitting display device 100 of FIG. 1 except for a leakage current blocking layer 340, a hole transport layer 350, and a light emitting layer 360. Accordingly, explanation of the light emitting display device 300 according to still another embodiment of the present invention will be primarily focused on the leakage current blocking layer 340, the hole transport layer 350, and the light emitting layer 360.

The light emitting display device 300 according to still another embodiment of the present invention includes substrate 105, a first electrode 110, a pixel defining layer 120, a hole injection layer 130, a leakage current blocking layer 340, a hole transport layer 350, a light emitting layer 360, an electron transport layer 170, an electron injection layer 180, and a second electrode 190. These members are sequentially stacked in a Z direction of FIG. 6.

The leakage current blocking layer 340 is similar to the leakage current blocking layer 140 of FIG. 2. However, the leakage current blocking layer 340 is disposed between the hole transport layer 350 and the light emitting layer 360. The leakage current blocking layer 340 may have the same or substantially the same function as the leakage current blocking layer 140 of FIG. 2.

The hole transport layer 350 is similar to the hole transport layer 150 of FIG. 2. However, the hole transport layer 350 is disposed between the hole injection layer 130 and the leakage current blocking layer 340. The hole transport layer 350 may have the same or substantially the same function as the hole transport layer 150 of FIG. 2.

The light emitting layer 360 is similar to the light emitting layer 160 of FIG. 2. However, the light emitting layer 360 is disposed on the hole transport layer 350 and the leakage current blocking layer 340 in the opening OP of the pixel defining layer 120. The light emitting layer 360 may have the same or substantially the same function as the light emitting layer 160 of FIG. 2.

As described above, the light emitting display device 300 according to still another embodiment of the present invention includes the leakage current blocking layer 340, with a uniform thickness, disposed on the side surface of the pixel defining layer 120 between the first electrode 110 and the light emitting layer 360 at a region where a distance between the first electrode 110 and the second electrode 190 becomes smaller due to the portion having a decreasing thickness in the light emitting layer 360. This is because the light emitting layer 160 disposed in the opening OP of the pixel defining layer 120 has decreasing thickness at the portion corresponding to the side surface of the pixel defining layer 120.

Accordingly, the light emitting display device 300 according to still another embodiment of the present invention may decrease the deterioration of light emission efficiency of the light emitting layer 360 by decreasing or preventing the occurrence of a leakage current between the first electrode 110 and the second electrode 190, and thus the deterioration of display quality may be decreased.

The electron transport layer 270 and the electron injection layer 280 illustrated in FIG. 5 may be applied to the light emitting layer 360 instead of the electron transport layer 170 and the electron injection layer 180.

Next, a light emitting display device 400 according to still another embodiment of the present invention will be described.

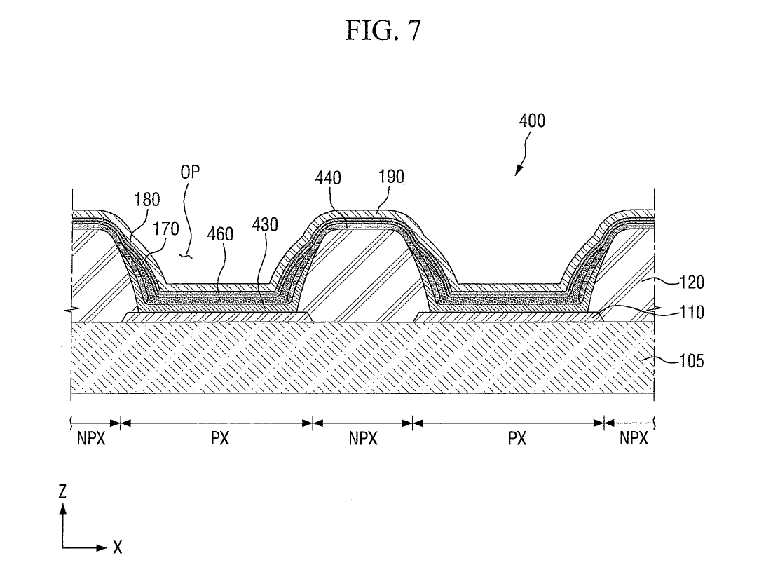

FIG. 7 is cross-sectional view of a light emitting display device according to still another embodiment of the present invention.

Referring to FIG. 7, the light emitting display device 400 according to still another embodiment of the present invention has the same or substantially the same configuration as the configuration of the light emitting display device 100 of FIG. 1 except for a first common layer 430, a leakage current blocking layer 440, and a light emitting layer 460. Accordingly, explanation of the light emitting display device 400 according to still another embodiment of the present invention will be primarily focused on the first common layer 430, the leakage current blocking layer 440, and the light emitting layer 460.

The light emitting display device 400 according to still another embodiment of the present invention includes substrate 105, a first electrode 110, a pixel defining layer 120, a first common layer 430, a leakage current blocking layer 440, a light emitting layer 460, an electron transport layer 170, an electron injection layer 180, and a second electrode 190. These members are sequentially stacked in a Z direction of FIG. 7.

The first common layer 430 may be disposed along the first electrode 110 and the side surface of the pixel defining layer 120 in the opening OP of the pixel defining layer 120. The first common layer 430 may be formed by discharging a first common solution including a first common material into the opening OP of the pixel defining layer 120 using an inkjet printing method, a nozzle printing method, or the like. In this case, the first common layer 430 may have a thickness decreasing toward the side surface of the pixel defining layer 120 from the first electrode 110. The first common layer 430 may be the hole injection layer 130 or the hole transport layer 150 shown in FIG. 2. That is, the hole transport layer 150 or the hole injection layer 130 illustrated in FIG. 2 may be omitted in the light emitting display device 400.

The first common layer 430 may be applied to the light emitting display device 200 of FIG. 5 in which the hole transport layer is omitted, instead of the hole injection layer 130.

The leakage current blocking layer 440 is similar to the leakage current blocking layer 140 of FIG. 2. However, the leakage current blocking layer 440 may be disposed between the first common layer 430 and the light emitting layer 460. The leakage current blocking layer 440 may have the same or substantially the same function as the leakage current blocking layer 140 of FIG. 2.

The light emitting layer 460 is similar to the light emitting layer 160 of FIG. 2. However, the light emitting layer 460 is disposed on the first common layer 430 and the leakage current blocking layer 440 in the opening OP of the pixel defining layer 120. The light emitting layer 460 may have the same or substantially the same function as the light emitting layer 160 of FIG. 2.

As described above, the light emitting display device 400 according to still another embodiment of the present invention includes the leakage current blocking layer 440, with a uniform thickness, disposed on the side surface of the pixel defining layer 120 between the first electrode 110 and the light emitting layer 460 at a region where a distance between the first electrode 110 and the second electrode 190 becomes smaller through the portion having a decreasing thickness in the light emitting layer 360. This is because the light emitting layer 460 disposed in the opening OP of the pixel defining layer 120 has decreasing thickness at the portion corresponding to the side surface of the pixel defining layer 120.

Accordingly, the light emitting display device 400 according to still another embodiment of the present invention may decrease the deterioration of light emission efficiency of the light emitting layer 460 by decreasing or preventing the occurrence of a leakage current between the first electrode 110 and the second electrode 190, and thus the deterioration of display quality may be decreased.

Next, a light emitting display device 500 according to still another embodiment of the present invention will be described.

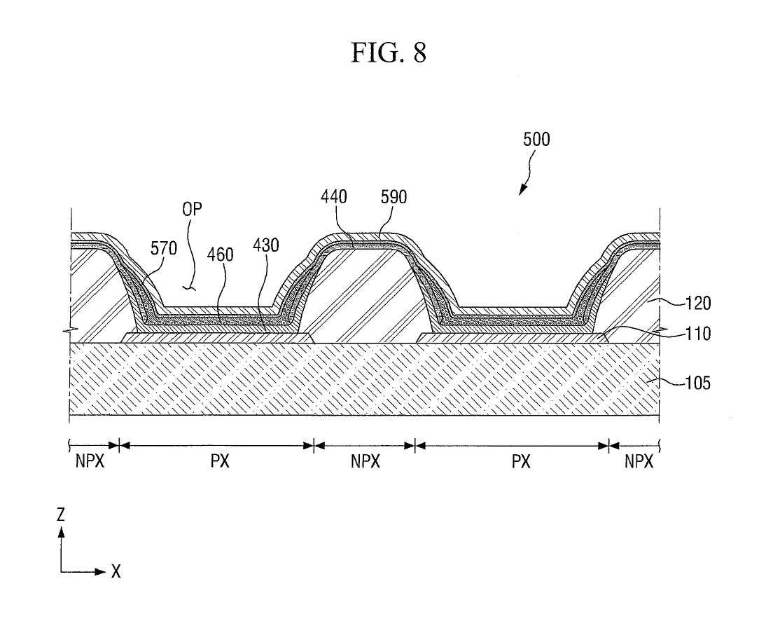

FIG. 8 is cross-sectional view of a light emitting display device according to still another embodiment of the present invention.

Referring to FIG. 8, the light emitting display device 500 according to still another embodiment of the present invention has the same or substantially the same configuration as the configuration of the light emitting display device 100 of FIG. 1 except for a first common layer 430, a leakage current blocking layer 440, a light emitting layer 460, a second common layer 570, and a second electrode 590. Accordingly, explanation of the light emitting display device 500 according to still another embodiment of the present invention will be primarily focused on the first common layer 430, the leakage current blocking layer 440, the light emitting layer 460, the second common layer 570, and the second electrode 590.

The light emitting display device 500 according to still another embodiment of the present invention includes substrate 105, a first electrode 110, a pixel defining layer 120, a first common layer 430, a leakage current blocking layer 440, a light emitting layer 460, a second common layer 570, and a second electrode 590. These members are sequentially stacked in a Z direction of FIG. 8.

The first common layer 430, the leakage current blocking layer 440, and the light emitting layer 460 have been described in detail in the above described embodiment, and thus a redundant description thereof may not be provided.

The second common layer 570 may be disposed on the light emitting layer 460 to have a continuous form between the adjacent pixels PX. The second common layer 570 may be the electron transport layer 170 or the electron injection layer 180 illustrated in FIG. 2. That is, the electron injection layer 180 or the electron transport layer 170 illustrated in FIG. 2 may be omitted in the light emitting display device 500. The second common layer 570 may be formed by, for example, a deposition method, or any other suitable method.

The second common layer 570 may be applied to the light emitting display device 100 of FIG. 2 instead of the electron transport layer 170 and the electron injection layer 180, to the light emitting display device 200 of FIG. 5 instead of the electron transport layer 270 and the electron injection layer 280, or to the light emitting display device 600 of FIG. 6 instead of the electron transport layer 170 and the electron injection layer 180.

The second electrode 590 is similar to the second electrode 190 of FIG. 2. However, the second electrode 590 is disposed on the second common layer 570. The second electrode 590 may have the same or substantially the same function as the second electrode 190 of FIG. 2.

As described above, the light emitting display device 500 according to still another embodiment of the present invention includes the leakage current blocking layer 440, with a uniform thickness, disposed on the side surface of the pixel defining layer 120 between the first electrode 110 and the light emitting layer 460 at a region where a distance between the first electrode 110 and the second electrode 590 becomes smaller through the portion having a decreasing thickness in the light emitting layer 360. This is because the light emitting layer 460 disposed in the opening OP of the pixel defining layer 120 has decreasing thickness at the portion corresponding to the side surface of the pixel defining layer 120.

Accordingly, the light emitting display device 500 according to still another embodiment of the present invention may decrease the deterioration of light emission efficiency of the light emitting layer 460 by decreasing or preventing the occurrence of a leakage current between the first electrode 110 and the second electrode 590, and thus the deterioration of display quality may be decreased.

Next, a light emitting display device 600 according to still another embodiment of the present invention will be described.

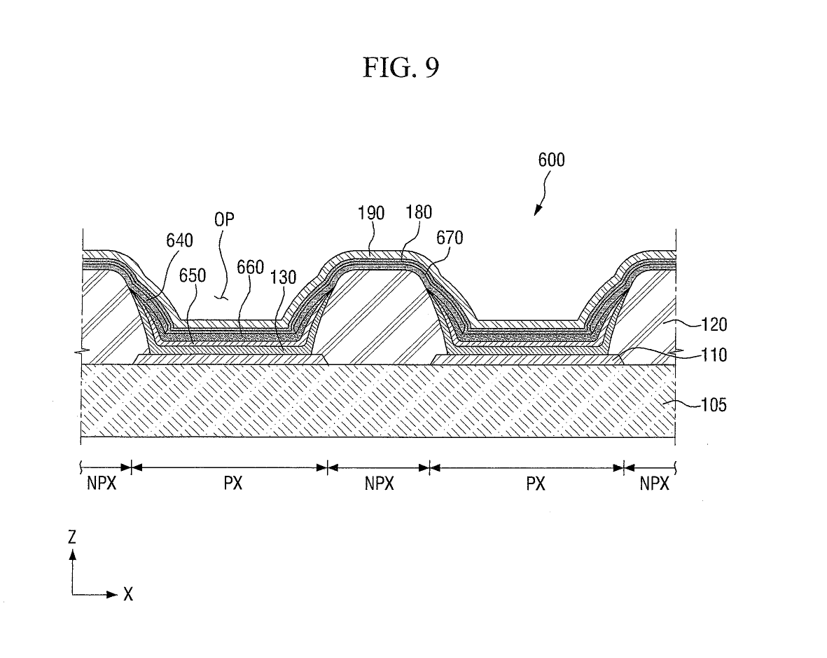

FIG. 9 is cross-sectional view of a light emitting display device according to still another embodiment of the present invention.

Referring to FIG. 9, the light emitting display device 400 according to still another embodiment of the present invention has the same or substantially the same configuration as the configuration of the light emitting display device 100 of FIG. 1 except for a leakage current blocking layer 640, an hole transport layer 650, a light emitting layer 660, and an electron transport layer 670. Accordingly, explanation of the light emitting display device 600 according to still another embodiment of the present invention will be primarily focused on the leakage current blocking layer 640, the hole transport layer 650, the light emitting layer 660, and the electron transport layer 670.

The light emitting display device 600 according to still another embodiment of the present invention includes substrate 105, a first electrode 110, a pixel defining layer 120, a hole injection layer 130, a leakage current blocking layer 640, a hole transport layer 650, a light emitting layer 660, an electron transport layer 670, an electron injection layer 180, and a second electrode 190. These members are sequentially stacked in a Z direction of FIG. 9.

The leakage current blocking layer 640 is similar to the leakage current blocking layer 140 of FIG. 2. However, the leakage current blocking layer 640 is disposed on the side surface of the pixel defining layer 120 between the light emitting layer 660 and the second electrode 190. For example, the leakage current blocking layer 640 may be disposed on a side portion of the light emitting layer 660 disposed on the side surface of the pixel defining layer 120, between the light emitting layer 660 and the electron transport layer 670.

Further, because the electron transport layer 670 is formed on the leakage current blocking layer 640 by a deposition method, it is not required that the leakage current blocking layer 640 has a lyophobic property. Accordingly, the leakage current blocking layer 640 may be formed of an insulating material having an electric resistance higher than an electric resistance of the light emitting layer 660 in order to prevent or substantially prevent a leakage current from flowing between the first electrode 110 and the second electrode 190. Thus, the leakage current blocking layer 640 may be formed of an inorganic insulating material such as silicon Oxide, Silicon Nitride, silicon Oxynitride, and/or the like. In this case, the leakage current blocking layer 640 may be formed by a sputtering deposition method having a high straightness. The sputtering deposition method is a method of depositing a deposition material on a substrate, which applies impact to a surface of a target that is made of the deposition material by particles having energy and thus makes the deposition material secede and discharge from the surface of the target through momentum exchange at the time of the impact. Further, leakage current blocking layer 640 may be formed of an organic insulating material. The organic insulating material may be at least one polymer resin selected from the group including benzo cyclo butane (BCB), polyimide (PI), poly amaide (PA), acryl resin, phenol resin, and the like. In this case, the leakage current blocking layer 640 may be formed by an evaporation deposition method.

The leakage current blocking layer 640 may have the same or substantially the same function as the leakage current blocking layer 140 of FIG. 2.

The hole transport layer 650 is similar to the hole transport layer 150 of FIG. 2. However, the hole transport layer 650 is disposed between the hole injection layer 130 and the light emitting layer 660. The hole transport layer 650 may have the same or substantially the same function as the hole transport layer 150 of FIG. 2.

The light emitting layer 660 is similar to the light emitting layer 160 of FIG. 2. However, the light emitting layer 660 is disposed on the hole transport layer 650 and the leakage current blocking layer 640 in the opening OP of the pixel defining layer 120. The light emitting layer 660 may have the same or substantially the same function as the light emitting layer 160 of FIG. 2.

The electron transport layer 670 is similar to the electron transport layer 170 of FIG. 2. However, the electron transport layer 670 is disposed on the light emitting layer 660 and the leakage current blocking layer 640. The electron transport layer 670 may have the same or substantially the same function as the electron transport layer 170 of FIG. 2.

As described above, the light emitting display device 600 according to still another embodiment of the present invention includes the leakage current blocking layer 640, with a uniform thickness, disposed on the side surface of the pixel defining layer 120 between the light emitting layer 660 and the second electrode 190 at a region where a distance between the first electrode 110 and the second electrode 190 becomes smaller through the portion having a decreasing thickness in the light emitting layer 360. This is because the light emitting layer 660 disposed in the opening OP of the pixel defining layer 120 has decreasing thickness at the portion corresponding to the side surface of the pixel defining layer 120.

Accordingly, the light emitting display device 600 according to still another embodiment of the present invention may decrease the deterioration of light emission efficiency of the light emitting layer 660 by decreasing or preventing the occurrence of a leakage current between the first electrode 110 and the second electrode 190, and thus the deterioration of display quality may be decreased.

The electron transport layer 270 and the electron injection layer 280 of FIG. 5 may be applied to the light emitting display device 600 of FIG. 9 instead of the electron transport layer 670 and the electron injection layer 180, the first common layer 430 of FIG. 7 may be applied to the light emitting display device 600 of FIG. 9 in which the hole transport layer 650 is omitted instead of the hole injection layer 130, the second common layer 570 of FIG. 8 may be applied to the light emitting display device 600 of FIG. 9 instead of the electron transport layer 670 and the electron injection layer 180, or the first common layer 430 of FIG. 7 may be applied to the light emitting display device 600 FIG. 9 in which the hole transport layer 650 is omitted instead of the hole injection layer 130 and the second common layer 570 of FIG. 8 may be applied to the light emitting display device 600 of FIG. 9 instead of the electron transport layer 670 and the electron injection layer 180.

Next, an example method of manufacturing light emitting display devices according to various embodiments of the present invention will now be described.

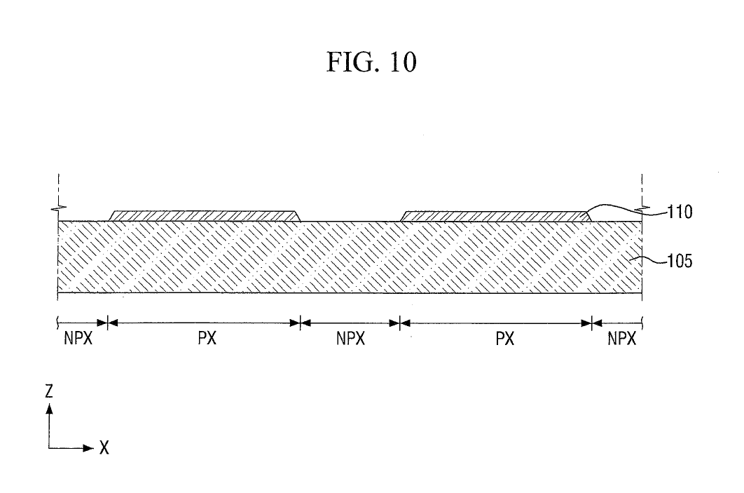

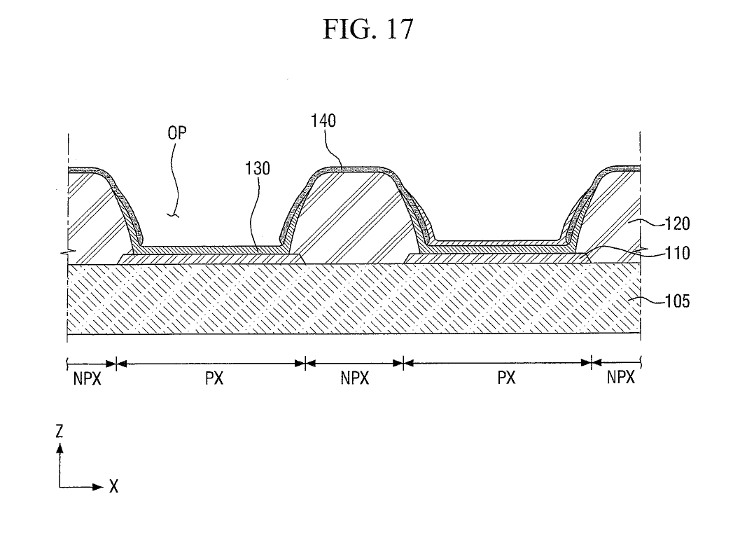

FIGS. 10 through 20 are views illustrating a method of manufacturing a light emitting display device according to an embodiment of the present invention.

Referring to FIG. 10, a first electrode 110 is formed on a substrate 105 having a plurality of pixels for each of the plurality of pixels PX. The first electrode 110 may be formed by depositing a transparent electrode material or a reflective material on the substrate 105 and patterning the transparent electrode material or the reflective material.

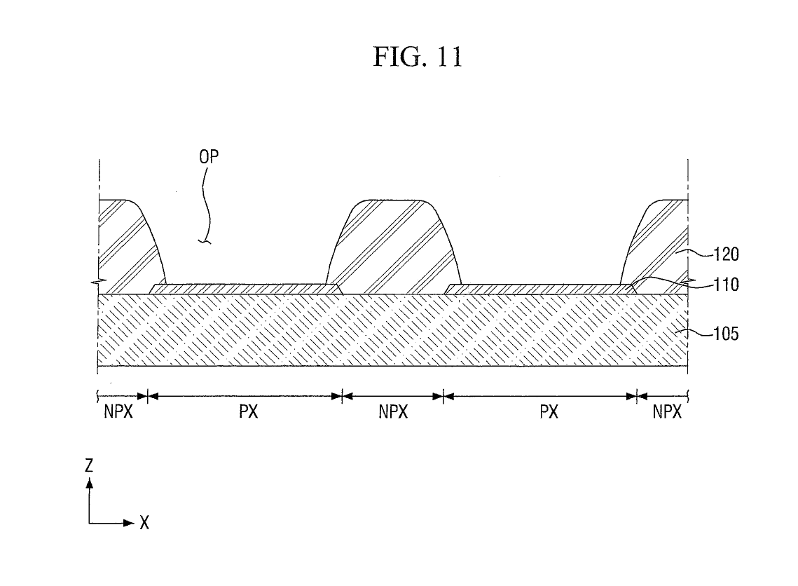

Then, referring to FIG. 11, a pixel defining layer 120 is formed on the substrate 105 to partition each pixel PX and to have an opening OP that exposes the first electrode 110. The pixel defining layer 120 may be formed by depositing an insulating material on the whole surface of the substrate 105 to cover the first electrode 110 using a deposition method and patterning the deposited insulating material.

The pixel defining layer 120 is formed to have a lyophobic property in order to prevent or substantially prevent a hole injection solution from going out the opening OP of the pixel defining layer 120 when forming the hole injection layer 130 by discharging the hole injection solution into the opening OP of the pixel defining layer 120 using an ink printing method, a nozzle printing method, or the like. For example, the pixel defining layer 120 may be formed of an insulating material that makes a contact angle of a hole injection solution against the pixel defining layer 120 become greater than or equal to about 40°.

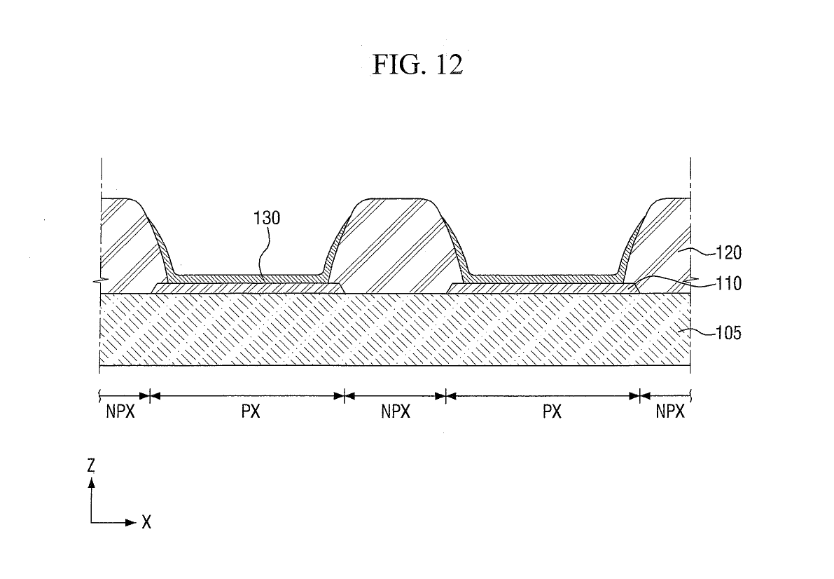

Then, referring to FIG. 12, a hole injection layer 130 is formed on the first electrode 110. The hole injection layer 130 may be disposed along the first electrode 110 and the side surface of the pixel defining layer 120 in the opening OP of the pixel defining layer 120. The hole injection layer 130 may be formed by discharging a hole injection solution into the opening OP of the pixel defining layer 120 using an inkjet printing method, a nozzle printing method, or the like. In this case, the hole injection layer 130 may have a thickness decreasing toward the side surface of the pixel defining layer 120 from the first electrode 110.

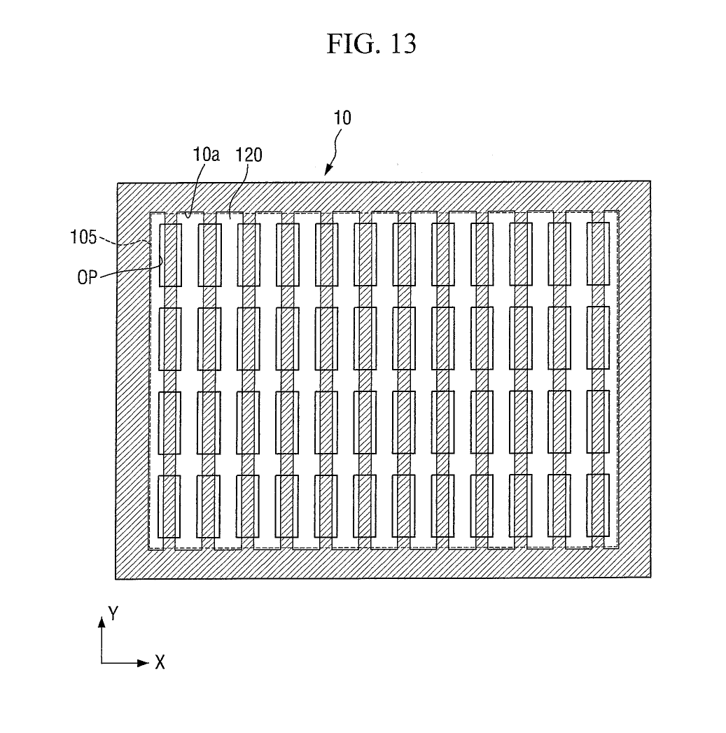

Then, referring to FIGS. 13 through 17, a leakage current blocking layer 140 is formed on the side surface (For example, the side portion of the hole injection layer 130 illustrated in FIG. 12) and an upper surface of the pixel defining layer 120 in the opening OP of the pixel defining layer 120.

For example, as illustrated in FIG. 13, a first mask 10 having first openings 10a is disposed on the substrate 105 including the hole injection layer 130 illustrated in FIG. 12. The first openings 10a are disposed to expose side portions of the hole injection layer 130 (see, e.g., FIG. 12) facing each other in the first direction X in the opening OP of the pixel defining layer 120. In this case, the first openings 10a may be formed to extend along the second direction Y and have a continuous form between adjacent openings OP of the pixel defining layer 120 in the first direction X.

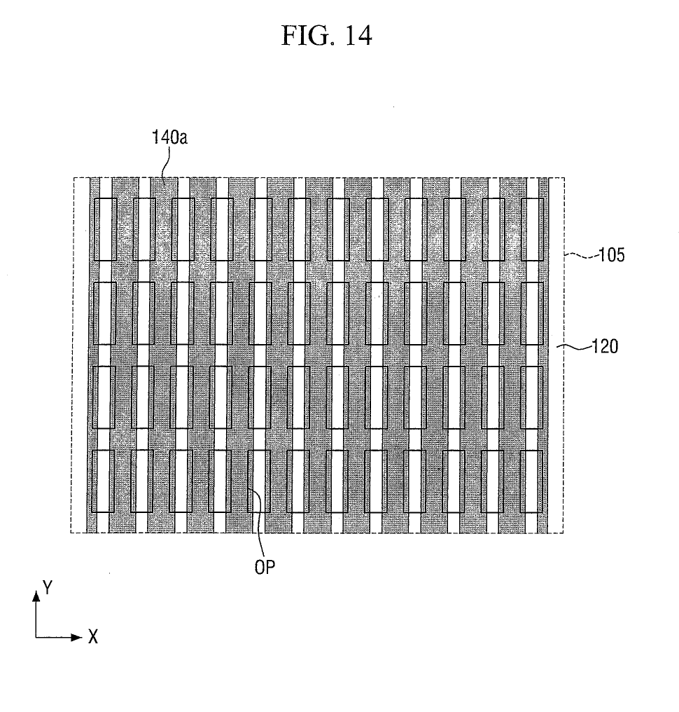

After the first mask 10 having the first openings 10a is disposed on the substrate 105 including the hole injection layer 130 illustrated in FIG. 12, a material forming (or a forming material of) the leakage current blocking layer 140 is deposited on the side portions of the hole injection layer 130 (see, e.g., FIG. 12) and on the upper surface of the pixel defining layer 120, which are exposed through the first openings 10a of the first mask 10 using a deposition method such as evaporation deposition method. Then, as illustrated in FIG. 14, first blocking portions 140a are formed on the side portions of the hole injection layer 130 (see, e.g., FIG. 12) and on the upper surface of the pixel defining layer 120, which are exposed through the first openings 10a of the first mask 10.

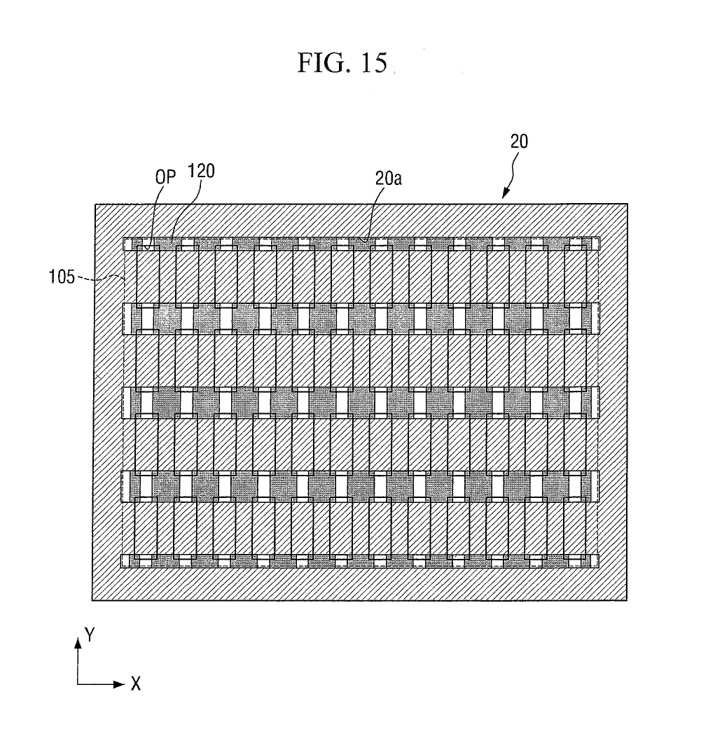

After the first blocking portions 140a are formed, a second mask 20 having second openings 20a is disposed on the substrate 105 including the first blocking portions 140a, as illustrated in FIG. 15. The second openings 20a are disposed to expose side portions of the hole injection layer 130 (see, e.g., FIG. 12) facing each other in the second direction Y in the opening OP of the pixel defining layer 120. In this case, the second openings 20a may be formed to extend along the first direction X and have a continuous form between adjacent openings OP of the pixel defining layer 120 in the second direction Y.

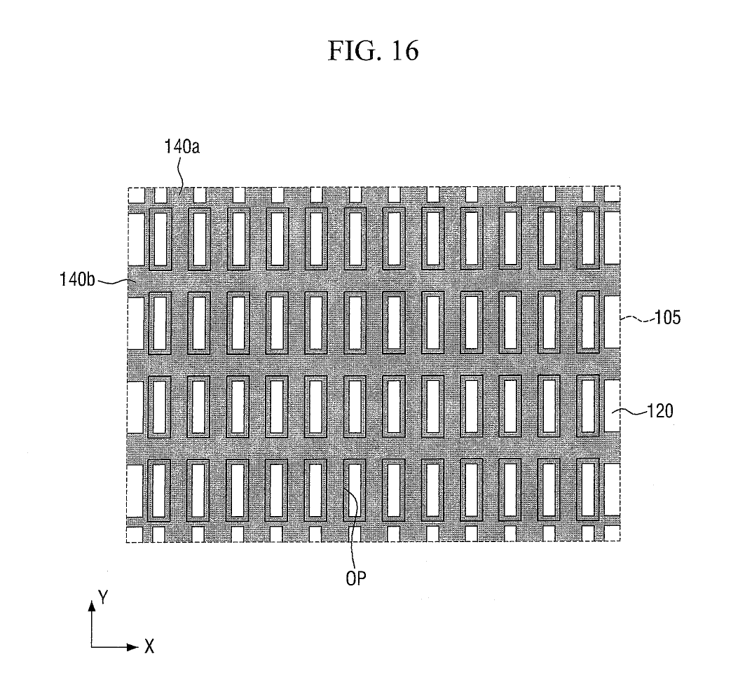

After the second mask 20 having the second openings 20a is disposed on the substrate 105 including the first blocking portions 140a, the material forming (or the forming material) of the leakage current blocking layer 140 is deposited on the side portions of the hole injection layer 130 (see, e.g., FIG. 12) and on the upper surface of the pixel defining layer 120, which are exposed through the second openings 20a of the second mask 20 using a deposition method such as evaporation deposition method. Then, as illustrated in FIG. 16, second blocking portions 140b are formed on the side portions of the hole injection layer 130 (see, e.g., FIG. 12) and on the upper surface of the pixel defining layer 120, which are exposed through the second openings 20a of the second mask 20.

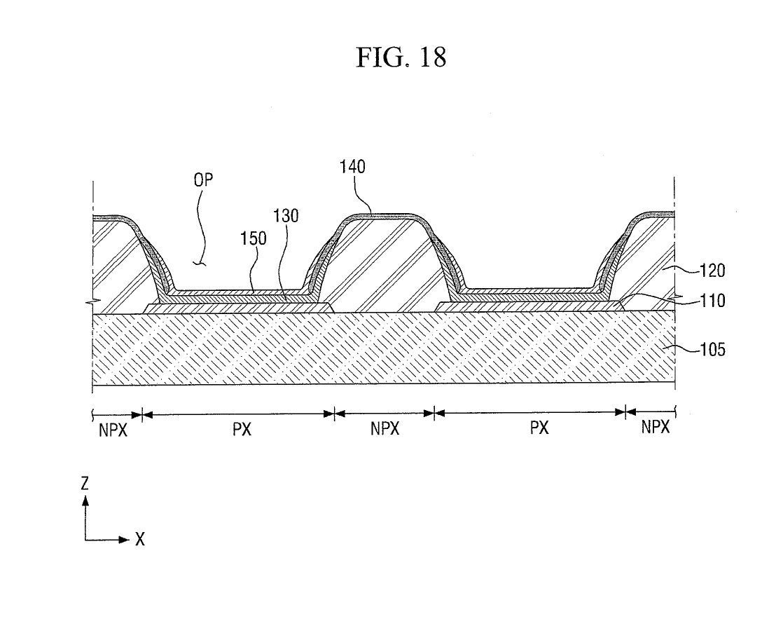

Then, referring to FIG. 18, a hole transport layer 150 is formed on the hole injection layer 130 and the leakage current blocking layer 140 in the opening OP of the pixel defining layer 120. The hole transport layer 150 may be formed by discharging a hole transport solution into the opening OP of the pixel defining layer 120 using an inkjet printing method, a nozzle printing method, or the like. In this case, the hole transport layer 150 may have a thickness decreasing toward the side surface of the pixel defining layer 120 from the first electrode 110.

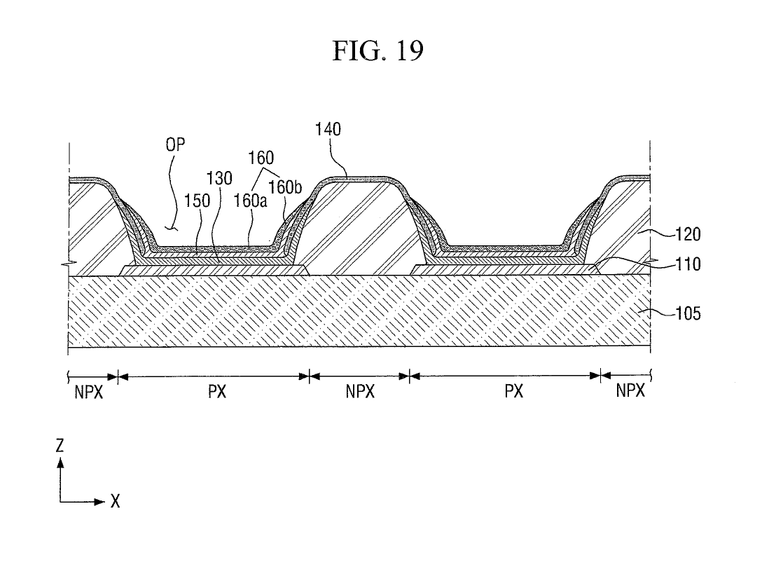

Then, referring to FIG. 19, a light emitting layer 160 is formed on the hole transport layer 150 in the opening OP of the pixel defining layer 120. The light emitting layer 160 may be formed by discharging a light emitting solution into the opening OP of the pixel defining layer 120 using an inkjet printing method, a nozzle printing method, or the like. In this case, the light emitting layer 160 may have a thickness decreasing toward the side surface of the pixel defining layer 120 from the first electrode 110. For example, the light emitting layer 160 may include a first portion 160a located on the first electrode 110 and a second portion 160b located on the side surface of the pixel defining layer 120. The first portion 160a may have a uniform thickness, and the second portion 160b may have a thickness decreasing in a direction toward the upper surface of the pixel defining layer from the side surface of the pixel defining layer 120.

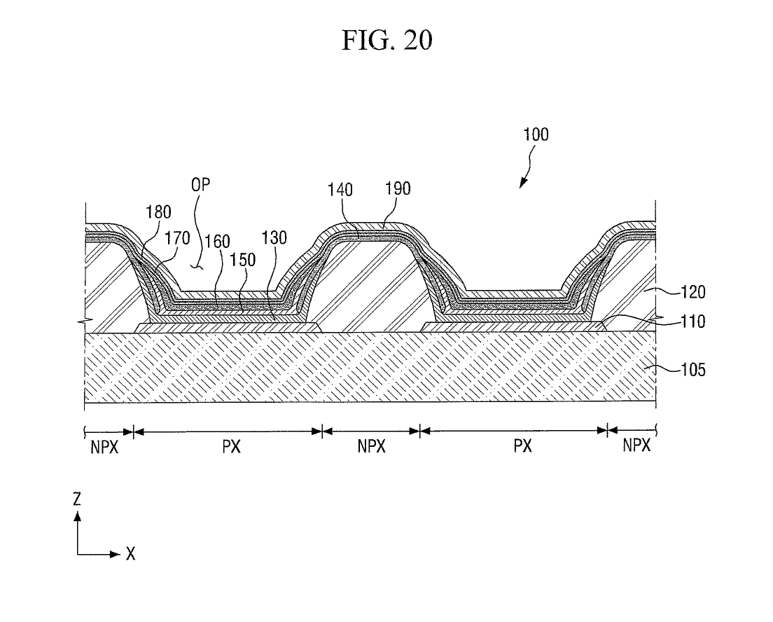

Then, referring to FIG. 20, an electron transport layer 170, an electron injection layer 180, and a second electrode 190 are formed on the light emitting layer 160. The electron transport layer 170, the electron injection layer 180, and the second electrode 190 may be sequentially formed using a deposition method.

The method of manufacturing a light emitting display device according to the embodiment may further include disposing an encapsulation substrate on the second electrode 190. In addition, the method of manufacturing a light emitting display device according to the embodiment may further include disposing a spacer between the second electrode 190 and the encapsulation substrate. Various suitable methods of placing the encapsulation substrate and placing the spacer are widely disclosed in the art to which the present invention pertains, and thus a detailed description thereof may not be provided.

In concluding the detailed description, those skilled in the art will appreciate that many variations and modifications may be made to the exemplary embodiments without substantially departing from the principles of the present invention. Therefore, the disclosed exemplary embodiments of the invention are used in a generic and descriptive sense, and not for purposes of limitation. Descriptions of features or aspects within each exemplary embodiment should typically be considered as available for other similar features or aspects in other exemplary embodiments.

While one or more exemplary embodiments have been described with reference to the figures, it will be understood by those of ordinary skill in the art that various suitable changes in form and details may be made therein without departing from the spirit and scope as defined by the following claim, and equivalents thereof.

It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

It will also be understood that when a layer is referred to as being “between” two layers, it can be the only layer between the two layers, or one or more intervening layers may also be present.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Further, the use of “may” when describing embodiments of the inventive concept refers to “one or more embodiments of the inventive concept.” Also, the term “exemplary” is intended to refer to an example or illustration.

It will be understood that when an element or layer is referred to as being “on” or “adjacent to” another element or layer, it can be directly on, connected to, coupled to, or adjacent to the other element or layer, or one or more intervening elements or layers may be present.

As used herein, the term “substantially,” “about,” and similar terms are used as terms of approximation and not as terms of degree, and are intended to account for the inherent variations in measured or calculated values that would be recognized by those of ordinary skill in the art.

As used herein, the terms “use,” “using,” and “used” may be considered synonymous with the terms “utilize,” “utilizing,” and “utilized,” respectively.

What is claimed is:

1. A light emitting display device comprising:
a substrate comprising a plurality of pixels arranged in a first direction and a second direction crossing the first direction;
a first electrode for each of the plurality of pixels on the substrate;
a pixel defining layer on the substrate and having an opening exposing the first electrode;
a light emitting layer extending along a side surface of the pixel defining layer from the first electrode in the opening of the pixel defining layer, and comprising a first portion located on the first electrode and a second portion located on the side surface of the pixel defining layer, the second portion having a thickness decreasing in a direction toward an upper surface of the pixel defining layer from the side surface of the pixel defining layer;
a second electrode on the light emitting layer; and
a leakage current blocking layer having a uniform thickness on the side surface of the pixel defining layer between the first electrode and the light emitting layer or between the light emitting layer and the second electrode.

2. The light emitting display device of claim 1, wherein the leakage current blocking layer has an electric resistance higher than an electric resistance of the light emitting layer.

3. The light emitting display device of claim 1, wherein the leakage current blocking layer comprises an organic insulating material or an inorganic insulating material.

4. The light emitting display device of claim 1, wherein the leakage current blocking layer has a continuous form between adjacent ones of the pixels.

5. The light emitting display device of claim 4, wherein the leakage current blocking layer has first blocking portions and second blocking portions that cross, the first blocking portions extending along the second direction and between openings of the pixel defining layer separated along the first direction, and the second blocking portions extending along the first direction and between openings of the pixel defining layer separated along the second direction.

6. The light emitting display device of claim 1, further comprising a hole injection layer between the first electrode and the light emitting layer in the opening of the pixel defining layer, the hole injection layer having a thickness decreasing toward the side surface of the pixel defining layer from the first electrode,
wherein the leakage current blocking layer is between the hole injection layer and the light emitting layer.

7. The light emitting display device of claim 1, further comprising a hole injection layer between the first electrode and the light emitting layer in the opening of the pixel defining layer, the hole injection layer having a thickness decreasing toward the side surface of the pixel defining layer from the first electrode, and
a hole transport layer between the hole injection layer and the light emitting layer in the opening of the pixel defining layer, the hole transport layer having a thickness decreasing toward the side surface of the pixel defining layer from the first electrode,
wherein the leakage current blocking layer is between the hole transport layer and the light emitting layer.

8. The light emitting display device of claim 1, further comprising an electron transport layer between the light emitting layer and the second electrode,
wherein the leakage current blocking layer is between the light emitting layer and the electron transport layer.

9. A light emitting display device comprising:
a substrate comprising a plurality of pixels arranged in a first direction and a second direction crossing the first direction;
a first electrode for each of the plurality of pixels on the substrate;
a pixel defining layer on the substrate and has an opening exposing the first electrode;
a light emitting layer extending along a side surface of the pixel defining layer from the first electrode in the opening of the pixel defining layer;
a second electrode on the light emitting layer; and
a leakage current blocking layer extending from the side surface of the pixel defining layer to an upper surface of the pixel defining layer between the first electrode and the light emitting layer or between the light emitting layer and the second electrode and having a continuous form between adjacent pixels.

10. The light emitting display device of claim 9, wherein the leakage current blocking layer has an electric resistance higher than an electric resistance of the light emitting layer.

11. The light emitting display device of claim 9, wherein the leakage current blocking layer is formed of an organic insulating material or an inorganic insulating material.

12. The light emitting display device of claim 9, wherein the leakage current blocking layer has first blocking portions and second blocking portions that cross, the first blocking portions extending along the second direction and between openings of the pixel defining layer separated along the first direction, and the second blocking portions extending along the first direction and between openings of the pixel defining layer separated along the second direction.

13. The light emitting display device of claim 9, wherein the light emitting layer comprises a first portion on the first electrode and a second portion on the side surface of the pixel defining layer, the second portion having a thickness decreasing in a direction toward an upper surface of the pixel defining layer from the side surface of the pixel defining layer.

14. The light emitting display device of claim 9, further comprising a hole injection layer between the first electrode and the light emitting layer in the opening of the pixel defining layer, the hole injection layer having a thickness decreasing toward the side surface of the pixel defining layer from the first electrode,
wherein the leakage current blocking layer is between the hole injection layer and the light emitting layer.

15. The light emitting display device of claim 9, further comprising a hole injection layer between the first electrode and the light emitting layer in the opening of the pixel defining layer, the hole injection layer having a thickness decreasing toward the side surface of the pixel defining layer from the first electrode, and
a hole transport layer between the hole injection layer and the light emitting layer in the opening of the pixel defining layer, the hole transport layer having a thickness decreasing toward the side surface of the pixel defining layer from the first electrode,
wherein the leakage current blocking layer is between the hole transport layer and the light emitting layer.

16. The light emitting display device of claim 9, further comprising an electron transport layer between the light emitting layer and the second electrode,
wherein the leakage current blocking layer is between the light emitting layer and the electron transport layer.

17. A method of manufacturing a light emitting display device, the method comprising:
forming a first electrode, on a substrate comprising a plurality of pixels arranged in a first direction and a second direction that crosses the first direction, for each of the plurality of pixels;
forming a pixel defining layer on the substrate and has an opening exposing the first electrode;
forming a light emitting layer along a side surface of the pixel defining layer from the first electrode in the opening of the pixel defining layer, the light emitting layer comprising a first portion located on the first electrode and a second portion located on the side surface of the pixel defining layer, the second portion having a thickness decreasing in a direction toward an upper surface of the pixel defining layer from the side surface of the pixel defining layer;
forming a second electrode on the light emitting layer; and
forming a leakage current blocking layer, having a uniform thickness, on the side surface of the pixel defining layer between the first electrode and the light emitting layer or between the light emitting layer and the second electrode.

18. The method of claim 17, wherein the forming the leakage current blocking layer comprises:
disposing a first mask having first openings on the substrate, the first openings exposing side portions of the pixel defining layer facing each other in the first direction in the opening of the pixel defining layer;
forming first blocking portions by depositing a material forming the leakage current blocking layer on a side surface and an upper surface of the pixel defining layer that are exposed through the first openings of the first mask using a deposition method;
disposing a second mask having second openings on the substrate, the second openings exposing side portions of the pixel defining layer facing each other in the second direction in the opening of the pixel defining layer; and
forming second blocking portions by depositing the material forming the leakage current blocking layer on a side surface and an upper surface of the pixel defining layer that are exposed through the second openings of the second mask using the deposition method.

19. The method of claim 18, wherein the first openings extend along the second direction and have a continuous form between adjacent openings of the pixel defining layer in the first direction, and
wherein the second openings extend along the first direction and have a continuous form between adjacent openings of the pixel defining layer in the second direction.

20. The method of claim 17, further comprising:
forming a hole injection layer, between the first electrode and the light emitting layer in the opening of the pixel defining layer, having a thickness decreasing toward the side surface of the pixel defining layer from the first electrode;
forming a hole transport layer, between the hole injection layer and the light emitting layer in the opening of the pixel defining layer, having a thickness decreasing toward the side surface of the pixel defining layer from the first electrode; and
forming an electron transport layer between the light emitting layer and the second electrode in the opening of the pixel defining layer,
wherein the forming the leakage current blocking layer comprises disposing the leakage current blocking layer between the hole injection layer and the hole transport layer, between the hole transport layer and the light emitting layer, or between the light emitting layer and the electron transport layer.
